(19) United States
(12) Patent Application Publication
(10) Pub. No.: US 2019/0103293 A1
(43) Pub. Date: Apr. 4, 2019

(54) SYSTEM AND METHOD FOR MANUFACTURING SEMICONDUCTOR DEVICE

(71) Applicant: SAMSUNG ELECTRONICS CO., LTD., Suwon-si (KR)

(72) Inventors: Hyun Bae KIM, Yongin-si (KR); Jin Ho KIM, Suwon-si (KR); Kwang Hyun CHO, Yongin-si (KR)

(21) Appl. No.: 16/002,240

(22) Filed: Jun. 7, 2018

(30) Foreign Application Priority Data
Sep. 29, 2017 (KR) 10-2017-0128077

(51) Int. Cl. H01L 21/67; H01J 37/32; G05B 13/02; G05B 19/418

(52) U.S. Cl. CPC H01L 21/67069; H01J 37/3244; H01J 37/32816; H01J 37/32183; G05B 2219/45031; G05B 13/0265; G05B 19/41825; H01J 2237/334; G05B 2219/34082; H01L 21/67253

(57) ABSTRACT

A system for manufacturing a semiconductor device includes a main system controller, a sub-system controller, and a process module. The main system controller provides a process recipe for manufacturing the semiconductor device and step identification information indicating one of a plurality of operations in the process recipe. The sub-system controller sets a process control variable based on the process recipe and the step identification information received from the main system controller. The process module perform the process recipe based on an input value determined by the process control variable

Korean Patent Application No. 10-2017-0128077, filed on Sep. 29, 2017, and entitled, “System and Method for Manufacturing Semiconductor Device,” is incorporated by reference herein in its entirety.

### BACKGROUND

### 1. Field

One or more embodiments described herein relate to a system and method for manufacturing a semiconductor device.

### 2. Description of the Related Art

Semiconductor devices are manufactured using various processes. Examples include exposure, etching, deposition, and ion implantation processes. These processes may be performed, for example, a system controller for controlling a number of process modules. In one implementation, the system controller includes a high-level main system controller and a low-level sub-system controller. The main system controller sends information to the sub-system controller to control the processes. The information may include, for example, process recipes and operations included in the process recipes.

### SUMMARY

In accordance with one or more embodiments, a system for manufacturing a semiconductor device includes a main system controller to provide a process recipe for manufacturing a semiconductor device and step identification information indicating one of a plurality of operations in the process recipe; a sub-system controller to set a process control variable based on the process recipe and the step identification information received from the main system controller; and a process module to perform the process recipe based on an input value determined by the process control variable.

The sub-system controller includes a memory to store information indicative of a history of process control variables determined in the operations; a basic controller to generate a basic process control variable based on a current value of the input value measured using a sensor and process control variables of an immediately previous operation; and an iterative learning controller to generate a learning process control variable based on the basic process control variable and the information indicative of the history of the process control variables stored in the memory, wherein process control variables of a current operation are to be determined based on basic process control variables and learning process control variables.

In accordance with one or more other embodiments, a system for manufacturing a semiconductor device includes a main system controller to provides a plasma etch recipe for manufacturing a semiconductor device and step identification information indicating one of a plurality of operations in the plasma etch recipe; an impedance matcher to set capacitance of a variable capacitor based on the plasma etch recipe and the step identification information received from the main system controller; and a plasma chamber which performs the plasma etch recipe based on a value of a voltage or current determined by the capacitance of the variable capacitor.

The impedance matcher includes: a memory to store information indicative of a history of capacitances of the variable capacitor determined in the operations; a basic controller to generate a basic process control variable based on a value of a current or voltage applied to the plasma chamber and capacitances of the variable capacitor in an immediately previous operation; and an iterative learning controller to generate a learning process control variable based on the basic process control variable and the information indicative of the history of the capacitances of the variable capacitor stored in the memory, capacitances of the variable capacitor in a current operation determined based on basic process control variables and learning process control variables.

In accordance with one or more other embodiments, a method for manufacturing a semiconductor device includes providing a process recipe for manufacturing a semiconductor device and step identification information indicating one of a plurality of operations in the process recipe from a main system controller to a sub-system controller; generating a basic process control variable based on process control variables of an operation immediately before a current operation indicated by the step identification information and an input value provided to a process module; generating a learning process control variable based on the basic process control variable and information indicative of a history of process control variables; and determining a process control variable of the current operation based on the basic process control variable and learning process control variable.

In accordance with one or more other embodiments, a non-transitory, computer-readable medium comprising instructions that when executed cause a processor to perform a method for manufacturing a semiconductor device, the method comprising providing a process recipe for manufacturing a semiconductor device and step identification information indicating one of a plurality of operations in the process recipe from a main system controller to a sub-system controller; generating a basic process control variable based on process control variables of an operation immediately before a current operation indicated by the step identification information and an input value provided to a process module; generating a learning process control variable based on the basic process control variable and a history of process control variables; and determining a process control variable of the current operation based on the basic process control variable and the learning process control variable.

### BRIEF DESCRIPTION OF THE DRAWINGS

Features will become apparent to those of skill in the art by describing in detail exemplary embodiments with reference to the attached drawings in which:

FIG. 1 illustrates an embodiment of a system for manufacturing a semiconductor device;

FIG. 2 illustrates a circuit embodiment of a system for manufacturing a semiconductor device;

FIG. 3 illustrates another embodiment of a system for manufacturing a semiconductor device;

FIG. 4 illustrates a flowchart of an embodiment of a method for manufacturing a semiconductor device;

FIG. 5 illustrates a graph for explain an embodiment including a recipe and a step identifier for manufacturing a semiconductor device;

FIG. 6 illustrates an embodiment for determining a process control variable;

FIG. 7 illustrates an embodiment for operating a memory; and

FIGS. 8 to 10 illustrate embodiments for manufacturing a semiconductor device.

### DETAILED DESCRIPTION

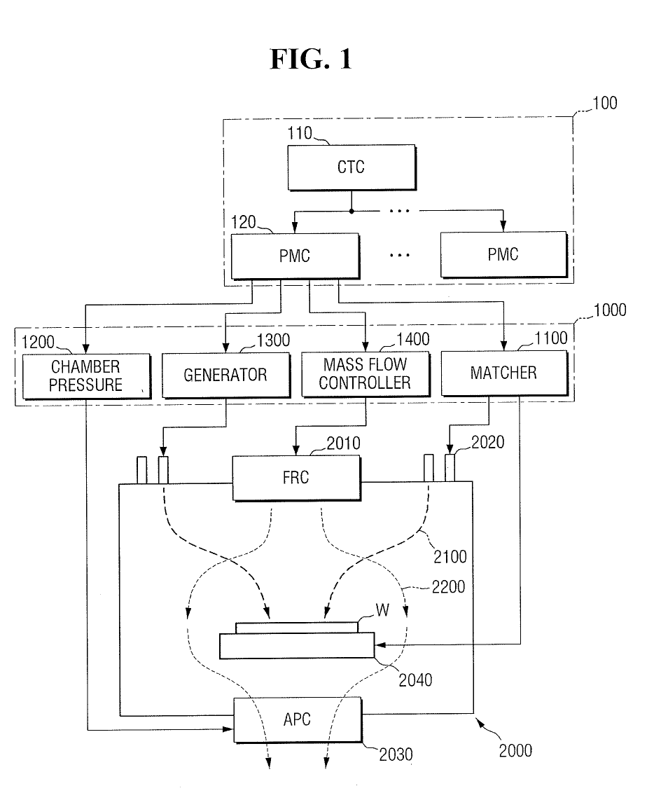

FIG. 1 illustrates an embodiment of a system for manufacturing a semiconductor device which, for example, may be for a plasma etching. The system may be a difference type of system and/or may perform a different operation in another embodiment.

Referring to FIG. 1, the system may include a main system controller 100, a sub-system controller 1000, and a process module 2000. The main system controller 100 may control the sub-system controller 1000 and the process module 2000. The main system controller 100 may include a cluster tool controller (CTC) 110 and process module controllers (PMCs) 120.

The CTC 110 may control the sub-system controller 1000 and the process module 2000 by setting a process recipe for processing a manufacturing process performed by the semiconductor device manufacturing system, and by setting a schedule of operations in the process recipe. The CTC 110 may be connected to one or more PMCs 120 and may interact with the PMCs 120.

Each of the PMCs 120 may provide information, corresponding to a process to be performed on a wafer W by the process module 2000, to the sub-system controller 1000. For example, each of the PMCs 120 may provide a recipe to be performed by the process module 2000 and step identification information (step ID) indicating one of a plurality of operations in the recipe to the sub-system controller 1000.

As illustrated in FIG. 1, a plurality of PMCs 120 may be connected to one CTC 110. Different or additional process modules 2000 may be connected to the PMCs 120, respectively, in other embodiments, and the PMCs 120 may control manufacturing processes performed by the different process modules 2000, respectively.

The sub-system controller 1000 may control the process module 2000 based on a recipe and step identification information received from the main system controller 100. For example, the sub-system controller 1000 may set a process control variable based on a recipe received from the main system controller 100 and step identification information included in the recipe. An input value provided to the process module 2000 is determined by the process control variable, and the process module 2000 performs a process of manufacturing a semiconductor device based on the input value.

When the system is a plasma etching system, the sub-system controller 1000 may include, for example, an impedance matcher 1100, a chamber pressure controller 1200, a generator 1300, and a mass flow controller 1400. The impedance matcher 1100 may be connected to a radio frequency (RF) electrode 2020 or a bottom electrode 2040. The impedance matcher 1100 may provide impedance matching to reduce or minimize reflected power of an electric circuit between the RF electrode 2020 and the bottom electrode 2040.

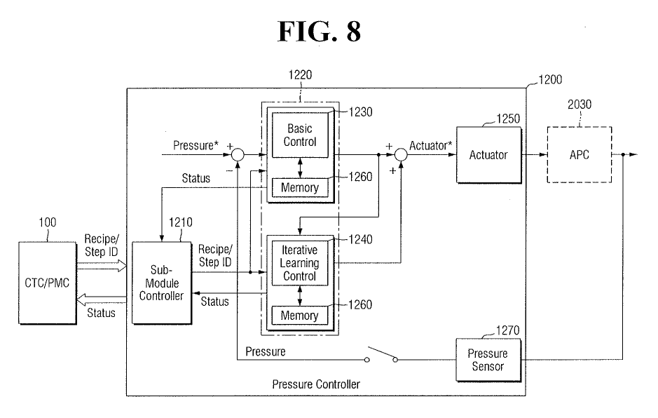

The chamber pressure controller 1200 may control the pressure inside a plasma etching chamber. For example, the chamber pressure controller 1200 may adjust the pressure inside the plasma etching chamber by controlling an automatic pressure control (APC) 2030 that discharges a gas 2200 supplied into the plasma etching chamber. An example will be described with reference to FIG. 8.

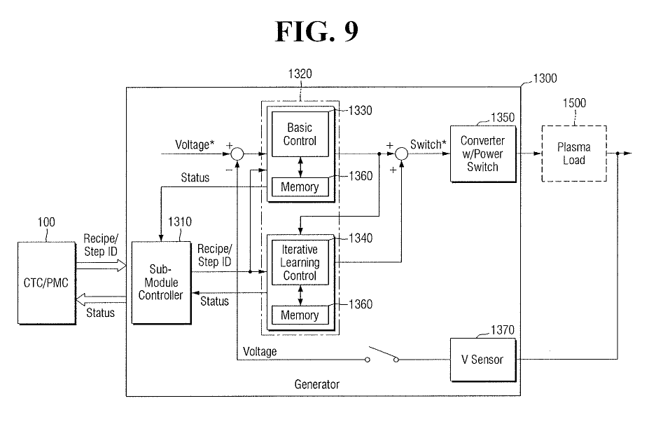

The generator 1300 may be connected to the RF electrode 2020. The generator 1300 may generate a voltage to be applied to a power source for forming plasma and inputting the plasma onto the wafer W in the form of ions 2100. An example of the generator 1300 in the plasma etching chamber will be described with reference to FIG. 9.

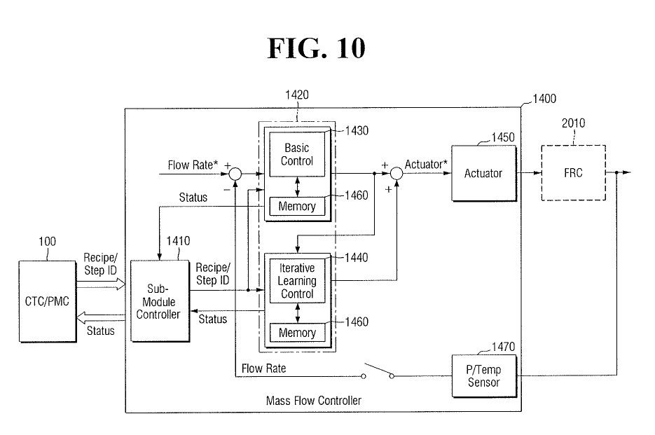

The mass flow controller 1400 may control the amount of gas supplied into the plasma etching chamber. For example, the mass flow controller 1400 may control the amount of gas supplied into the plasma etching chamber by controlling a flow rate control (FRC) 2010 that introduces the gas 2200 into the plasma etching chamber. An example will be described with reference to FIG. 10.

The process module 2000 may be a plasma etching chamber as illustrated in FIG. 1. When the process module 2000 is a plasma etching chamber, it may include the FRC 2010, the RF electrode 2020, the APC 2030, and the bottom electrode 2040.

The FRC 2010 may control the amount of the gas 2200 introduced into the plasma etching chamber. The FRC 2010 may include a valve driven by an actuator. The mass flow controller 1400 controls the degree of opening or closing of the valve which is determined by the amount of voltage or current supplied to the actuator. The amount of gas introduced into the plasma etching chamber is determined by the degree of opening or closing of the valve.

A process control variable set by the mass flow controller 1400 may correspond to the amount of voltage or current supplied to the actuator, and an input value determined by the process control variable may correspond to the amount of gas introduced into the plasma etching chamber by the valve driven by the actuator.

The RF electrode 2020 may form an electric circuit in the plasma etching chamber when receiving a voltage from the generator 1300. In addition, the RF electrode 2020 may be connected to the impedance matcher 110 and perform impedance matching to reduce or minimize the reflected power of the formed electric circuit. The RF electrode 2020 and the bottom electrode 2040 may be capacitively coupled to the gas 2200 supplied into the plasma chamber.

A process control variable set by the impedance matcher 1100 may be a capacitance value of a variable capacitor in the impedance matcher 1100. In addition, an input value determined by the process control variable may be the value of a voltage or current applied to the electrical circuit in the plasma etching chamber which is controlled by the impedance matcher 1100.

A process control variable set by the generator 1300 may be a switching cycle of a switch in the generator 1300. The generator 1300 may apply, for example, direct current (DC) pulse power to the RF electrode 2020 through the switching of the switch. The magnitude or the application cycle of the DC pulse power may be controlled by the switching cycle of the switch. Therefore, an input value determined by the process control variable may be the magnitude of the DC pulse power applied to the RF electrode 2020.

The APC 2030 may control the pressure inside the plasma etching chamber by adjusting the amount of the gas 2200 discharged from the plasma etching chamber. The APC 2030 may include a valve driven by an actuator. The chamber pressure controller 1200 controls the degree of opening or closing of the valve which is determined by the amount of voltage or current supplied to the actuator. The amount of gas discharged from the plasma etching chamber is controlled by the degree of opening or closing of the valve.

A process control variable set by the chamber pressure controller 1200 may correspond to the amount of voltage or current supplied to the actuator. An input value determined by the process control variable may correspond to the amount of gas discharged from the plasma etching chamber.

As described above, the impedance matcher 1100, the chamber pressure controller 1200, the generator 1300, and the mass flow controller 1400 in the sub-system controller 1000 set their respective process control variables. Input values provided to the process module 2000 may be determined by the process control variables. The FRC 2010, the RF electrode 2020, the APC 2030 and the bottom electrode 2040 in the process module 2000 may perform a process of manufacturing a semiconductor device based on their respective input values.

Hereinafter, a case where the sub-system controller 1000 is the impedance matcher 1100 of FIG. 1 will be described. In this case, the sub-system controller 1000 sets the capacitance value of the variable capacitor in the impedance matcher 1100 as a process control variable. Also, an input value provided to the process module 2000 is the value of a voltage or current applied to the electric circuit in the plasma etching chamber which is controlled by the impedance matcher 1100.

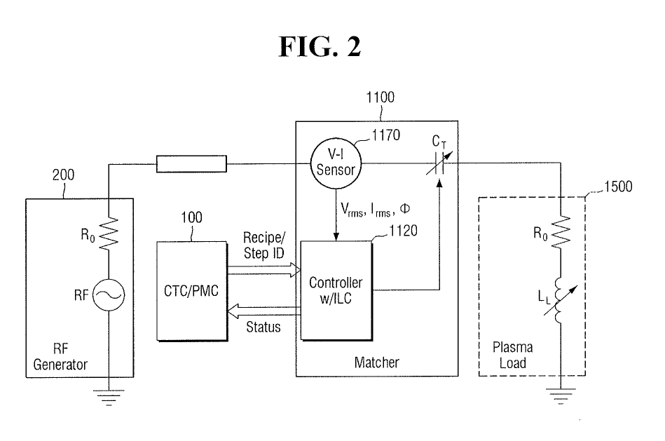

FIG. 2 illustrates an embodiment of the impedance matcher 1100 of FIG. 1. Referring to FIG. 2, the impedance matcher 1100 may perform impedance matching between an RF generator 200 and a plasma load 1500. In at least one embodiment, the term ‘impedance matching’ may refer to matching the impedance of the generator 200 to the impedance of the plasma load 1500.

In order to form plasma with maximum output in a plasma formation process of the system for manufacturing a semiconductor device, the reflected power of an electric circuit formed in a plasma chamber may be reduced or minimized. For example, the larger the reflected power generated from the electric circuit in the plasma chamber, the smaller the total output for plasma formation. The reflected power may be reduced or minimized by matching the impedance of the plasma load 1500 to the impedance of the RF generator 200. A controller 1120 including an iterative learning controller 1140 may adjust the capacitance of a variable capacitor 1150 to match the impedance of the plasma load 1500 and the impedance of the RF generator 200.

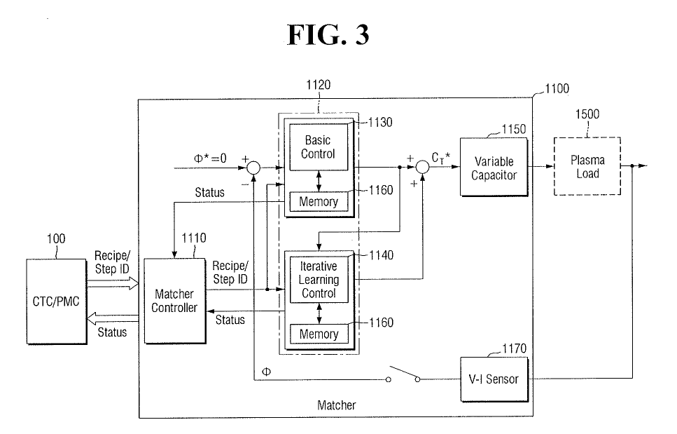

FIG. 3 illustrates an embodiment of the impedance matcher 1100 which may include a matcher controller 1110, a basic controller 1130, the iterative learning controller 1140, the variable capacitor 1150, a memory 1160, and a voltage-current sensor 1170.

The matcher controller 1110 may provide a recipe and step identification information received from the main system controller 100 to the basic controller 1130 and the iterative learning controller 1140. In addition, the matcher controller 1110 may provide process status information received from the basic controller 1130 and the iterative learning controller 1140 to the main system controller 100. The main system controller 100 may update a recipe or steps based on the process status information.

The basic controller 1130 may receive a current measured value of an input value determined by a process control variable set by the sub-system controller 1000. In the case of the impedance matcher 1100, the process control variable may be the capacitance of the variable capacitor 1150, and the input value determined by the process control variable may be the value of a voltage or current applied to the electrical circuit in the plasma etching chamber, as described above.

In addition, the basic controller 1130 may receive, from the memory 1160, the value of a process control variable used in a previous cycle based on a current point of a digital control cycle of an operation (or step) that should be performed. The value of the process control variable used in the previous cycle based on the current point of the digital control cycle may be the value of the variable capacitance of the basic controller 1130 used in the previous cycle.

Consequently, the basic controller 1130 generates a basic process control variable based on a phase difference φ, the capacitance value of the variable capacitor 1150 used in the previous cycle, and the current value of the voltage or current applied to the electric circuit in the plasma etching chamber.

The iterative learning controller 1140 may generate a learning process control variable based on a basic process control variable generated by the basic controller 1130 and a history of process control variables stored in the memory 1160.

The memory 1160 may store information indicative of a history of process control variables determined in a plurality of operations (or steps) in a recipe. For example, the system for manufacturing a semiconductor device performs a plurality of operations in a process recipe. The sub-system controller 1000 sets process control variables corresponding to each of the operations and provides input values determined based on the process control variables to the process module 2000. The memory 1160 may store information indicative of a history of process control variables set by the sub-system controller 1000 for each operation (or step). In addition, the memory 1160 may store process control variables to be set in an operation that has not been performed but is scheduled to be performed by the system for manufacturing a semiconductor device.

The capacitance of the variable capacitor 1150 may be controlled based on a basic process control variable generated by the basic controller 1130 and a learning process control variable generated by the iterative learning controller 1140. For example, the capacitance value of the variable capacitor 1150 may be determined to be a value obtained based on a sum of the basic process control variable and the learning process control variable. Once the capacitance value of the variable capacitor 1150 is determined, the value of a voltage or current to be applied to the plasma load 1500 may be determined based on the relationship between the RF generator 200, the variable capacitor 1150, and the plasma load 1500. The process module 2000 may perform a process recipe and operations in the process recipe based on the determined voltage or current value.

The voltage-current sensor 1170 measures the current value of a voltage or current applied to the electric circuit in the plasma etching chamber. The voltage-current sensor 1170 may calculate the phase difference φ of the electric circuit based on the measured voltage or current value. The voltage-current sensor 1170 provides the calculated phase difference φ to the basic controller 1130.

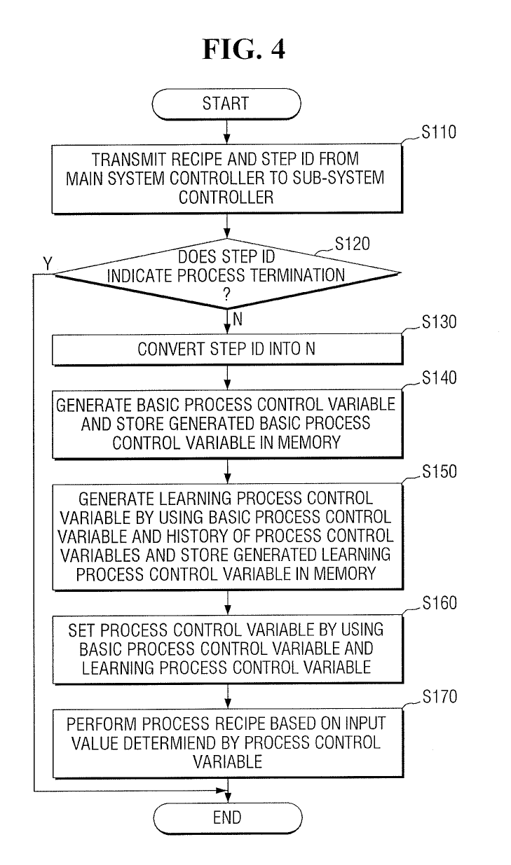

FIG. 4 illustrates a flowchart of an embodiment of a method for manufacturing a semiconductor device, which, for example, may be implemented using any of the embodiments of the system for manufacturing a semiconductor device described herein.

Referring to FIG. 4, the method includes transmitting a recipe and step identification information in the recipe from a main system controller 100 to a sub-system controller 1000 (operation S110). The main system controller 100 may provide a recipe to be performed by a process module 2000 and step identification information included in the recipe to the sub-system controller 1000.

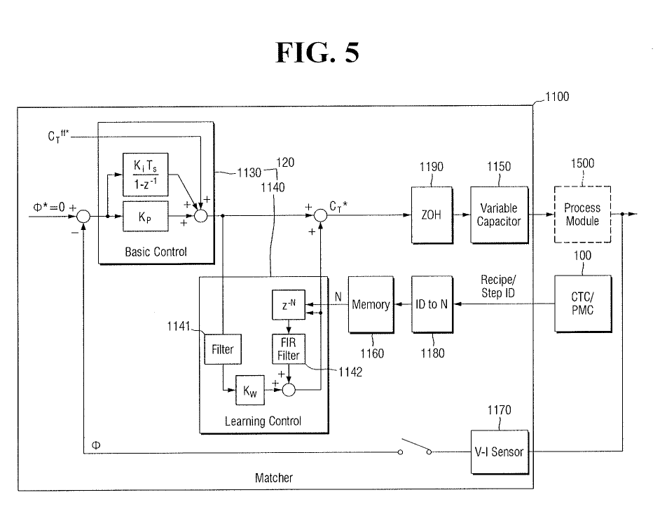

FIG. 5 illustrates a graph for explaining examples of a recipe and a step identifier provided by the main system controller 100 for manufacturing a semiconductor device. Referring to FIG. 5, a plurality of wafers (wafer 1 and wafer 2) are processed by the same recipe (recipe 1). Recipe 1 may include four operations (operation 1 to operation 4). The process module 2000 may perform recipe 1 based on process control variables corresponding to each of the four operations (operation 1 to operation 4) and input values determined based on the process control variables.

The main system controller 100 may provide information corresponding to a recipe and operations that should now be performed by the process module 2000 to the sub-system controller 1000. For example, the main system controller 100 may provide the sub-system controller 1000 with information indicating that recipe 1 and operation 3 in recipe 1 should now be performed by the process module 2000. The main system controller 100 may provide the sub-system controller 1000 with information about an operation, which should be performed by the process module 2000, in the form of step identification information (step ID). As illustrated in FIG. 5, the interval between the four operations (operation 1 to operation 4) may be, but is not limited to, about 200 ms.

Next, the sub-system controller 1000 determines whether the step identification information received from the main system controller 100 indicates process termination (operation S120). If the step identification information does not indicate process termination, it is converted into N (operation S130).

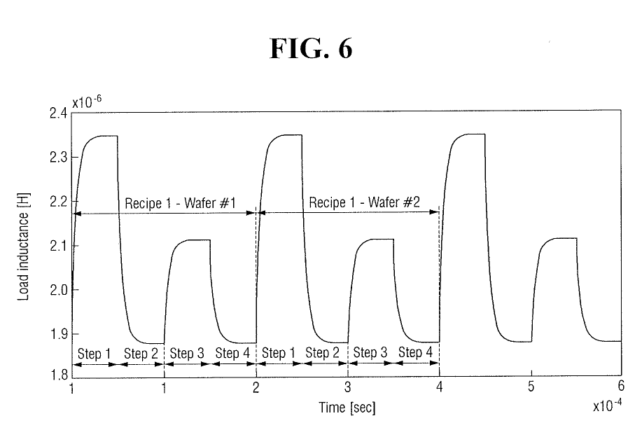

FIG. 6 illustrates an embodiment of a process in which the sub-system controller 1000 determines a process control variable. Referring to FIG. 6, a converter 1180 converts step identification information received from the main system controller 100 into N (operation S130). Here, N is a natural number indicating in which previous operation (or step) a digital control point is located based on a digital control point of a operation (or step) that should now be performed by the process module 2000. For example, a digital control cycle may be about 100 us, which is faster than a communication cycle with a host system.

Next, a basic controller 1130 generates a basic process control variable every digital cycle and stores the generated basic process control variable in a memory 1160 (operation S140). The basic controller 1130 may generate a basic process control variable using, for example, feed forward control and proportional-integral (PI) control.

In one embodiment, the basic controller 1130 may perform PI control by setting Kp illustrated in FIG. 6 as a proportional coefficient and setting Ki·Ts as a product of an integral coefficient and a digital control cycle. Here, Kp and Ki are respectively a p gain and an I gain, and Ts is the cycle of each digital control.

The basic controller 1130 may generate a basic process control variable based on a sum of a feed forward constant Ctff and the result value of the PI control. In FIG. 6, the basic controller 1130 generates a basic process control variable using the PI control. In one embodiment, the basic controller 1130 may also generate a basic process control variable using, for example, proportional-integral-derivative (PID) control.

In some cases, the basic controller 1130 may also generate a basic process control variable without adding the feed forward constant Ctff to the result of the PID control. The basic process control variable generated by the basic controller 1130 may be not only controlled by an iterative learning controller 1140 but also stored in the memory 1160 for subsequent computation of process control variables.

Next, the iterative learning controller 1140 generates a learning process control variable using the basic process control variable and information indicative of a history of process control variables stored in the memory 1160, and stores the generated learning process control variable in the memory 1160 (operation S150). The iterative learning controller 1140 may receive the information indicative of the history of process control variables stored in memory 1160.

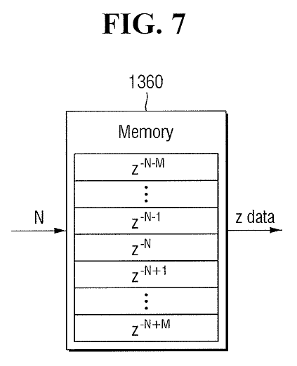

FIG. 7 illustrates an embodiment for operating the memory 1160 in FIG. 6. Referring to FIG. 7, the memory 1160 stores information indicative of a history of process control variables set by the sub-system controller 1000. For example, a previous Nth digital control point may be obtained by converting step identification information received from the main system controller 100. The previous Nth digital control point may be the same as a current control cycle point of a previous operation (or step). The memory 1160 may receive N and output data of process control variables at M (M is a natural number) digital control points before the Nth digital control point and process control variables at M digital control points after the Nth digital control point.

For example, when a process control variable at the Nth digital control point is Z-N, the process control variables at the M digital control points before the Nth digital control point may be Z-N−1, Z-N−2, . . . , Z-N−M, and the process control variables at the M digital control points after the Nth digital control point may be Z-N+1, Z-N+2, . . . , Z-N+M.

The memory 1160 may output the process control variable at the Nth digital control point and the M process control variables (Z-N−1, Z-N−2, . . . , Z-N−1, Z-N, Z-N+1, Z-N+2, . . . , Z-N+M) at the M digital control points before the Nth digital control point and at the M digital control points after the Nth digital control point to the iterative learning controller 1140.

Then, the iterative learning controller 1140 generates a learning process control variable based on a basic process control variable generated by the basic controller 1130 and information indicative of a history of process control variables output from the memory 1160. For example, the iterative learning controller 1140 may filter the basic process control variable using a filter 1141 and generate a learning process control variable based on a sum of a value obtained by multiplying the filtered basic process control variable by an iterative learning control gain Kw and a value obtained by passing the history information of the process control variables passes through a finite impulse response (FIR) filter 1142.

In one embodiment, the iterative learning controller 1140 may not filter the basic process control variable using the filter 1141 and generate a learning process control variable based on a sum of a value obtained by multiplying the unfiltered basic process control variable by the iterative learning control gain Kw and a value obtained by passing the history information of the process control variables through the FIR filter 1142. The iterative learning control gain Kw may be, for example, a coefficient having a value larger than 0 and smaller than 1. The size of the iterative learning control gain Kw may be determined by which of the basic process control variable and the history information of the process control variables will be given importance.

Next, a process control variable is set using the basic process control variable and the learning process control variable (operation S160). The setting of the process control variable may include adding the basic process control variable generated by the basic controller 1130 to the learning process control variable generated by the iterative learning controller 1140. An impedance matcher 1100 may determine the process control variable generated by adding the basic process control variable to the learning process control variable to be a capacitance value of a variable capacitor 1150.

In some embodiments, the impedance matcher 1100 may include a zero order hold (ZOH) 1190. The ZOH 1190 may function as a buffer for outputting the process control variable to the variable capacitor 1150.

Next, the process module 2000 performs the process recipe based on an input value determined based on the process control variable (operation S170). The input value determined based on the capacitance of the variable capacitor 1150 may correspond, for example, to the value of a voltage or current applied to a plasma load 1500.

In summary, the system for manufacturing a semiconductor device according to one or more embodiments may determine process control variables of a current operation (or step) based on process control variables determined in an operation (or step) before the current operation (or step) that should be performed by the process module 2000.

As described above, the main system controller 100 may receive process status information from the sub-system controller 1000 and update process conditions of a recipe and operations. However, it may be relatively slow for the main system controller 100 including a CTC 110 and PMCs 120 to update the process conditions according to the process status information received from the sub-system controller 1000.

For example, the sub-system controller 1000 may determine process control variables of a current operation based on process control variables in a previous operation using the iterative learning controller 1140 and the memory 1160. Therefore, the determination of process control variables by the sub-system controller 1000 may be faster than the update of process conditions by the main system controller 100 based on the communication between the main system controller 100 and the sub-system controller 1000.

FIGS. 8 to 10 illustrate embodiments of systems for manufacturing a semiconductor device. Referring to FIG. 8, a case where the sub-system controller 1000 is the chamber pressure controller 1200 of FIG. 1 is illustrated.

The chamber pressure controller 1200 may include a sub-module controller 1210, a basic controller 1230, an iterative learning controller 1240, an actuator 1250, a memory 1260, and a pressure sensor 1270. The chamber pressure controller 1200 may set the amount of voltage or current applied to the actuator 1250 as a process control variable.

The basic controller 1230 may generate a basic process control variable based on the pressure inside a plasma chamber measured by the pressure sensor 1270. The iterative learning controller 1240 may generate a learning process control variable by using the basic process control variable generated by the basic controller 1230 and information indicative of a history of process control variables stored in the memory 1260.

A process control variable determined by a controller 1220 is sent to the actuator 1250 in the form of a voltage or a current. The actuator 1250 may set the degree of opening or closing of a valve as an input value based on the received process control variable and transmit the input value to an APC 2030.

Referring to FIG. 9, a case where the sub-system controller 1000 is the generator 1300 of FIG. 1 is illustrated. The generator 1300 may include a sub-module controller 1310, a basic controller 1330, an iterative learning controller 1340, a converter 1350, a memory 1360, and a voltage sensor 1370. The generator 1300 may set a switching cycle of a power switch in the converter 1350 as a process control variable.

The basic controller 1330 may generate a basic process control variable based on a voltage applied to an RF electrode 2020 or a bottom electrode 2040 measured by the voltage sensor 1370. The iterative learning controller 1340 may generate a learning process control variable based on the basic process control variable generated by the basic controller 1330 and information indicative of a history of process control variables stored in the memory 1360.

A process control variable determined by a controller 1320 is sent to the converter 1350 in the form of a switching cycle. The converter 1350 may set the magnitude of DC pulse power as an input value based on the received process control variable and transmit the input value to the RF electrode 2020 or the bottom electrode 2040.

Referring to FIG. 10, a case where the sub-system controller 1000 is the mass flow controller 1400 of FIG. 1 is illustrated. The mass flow controller 1400 may include a sub-module controller 1410, a basic controller 1430, an iterative learning controller 1440, an actuator 1450, a memory 1460, and a pressure/temperature sensor 1470.

The mass flow controller 1400 may set the amount of voltage or current applied to the actuator 1450 as a process control variable.

The basic controller 1430 may generate a basic process control variable based on the pressure and temperature inside a plasma chamber measured by the pressure/temperature sensor 1470. The iterative learning controller 1440 may generate a learning process control variable based on the basic process control variable generated by the basic controller 1430 and information indicative of a history of process control variables stored in the memory 1460.

A process control variable determined by a controller 1420 is sent to the actuator 1450 in the form of a voltage or a current. The actuator 1450 may set the degree of opening or closing of a valve as an input value based on the received process control variable and transmit the input value to an FRC 2010.

The methods, processes, and/or operations described herein may be performed by code or instructions to be executed by a computer, processor, controller, modules, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods described herein.

The controllers, generators, processors, filters, modules, and other signal generating, providing, and processing features of the embodiments disclosed herein may be implemented in non-transitory logic which, for example, may include hardware, software, or both. When implemented at least partially in hardware, the controllers, generators, processors, filters, modules, and other signal generating, providing, and processing features may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the controllers, generators, processors, filters, modules, and other signal generating, providing, and processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

The various operations of methods described above may be performed by any suitable means capable of performing the operations, such as various hardware and/or software component(s), circuits, and/or module(s).

The software may comprise an ordered listing of executable instructions for implementing logical functions, and can be embodied in any “processor-readable medium” for use by or in connection with an instruction execution system, apparatus, or device, such as a single or multiple-core processor or processor-containing system.

The blocks or steps of a method or algorithm and functions described in connection with the embodiments disclosed herein may be embodied directly in hardware, in a software module executed by a processor, or in a combination of the two. If implemented in software, the functions and operations of the method and other embodiments described herein may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

In accordance with one or more of the aforementioned embodiments, a plasma may be formed with an increased or maximum output in a plasma formation process of the system for manufacturing a semiconductor device. This may be accomplished by reducing or minimizing reflected power of an electric circuit formed in a plasma chamber. The reflected power may be reduced or minimized by matching the impedance of a plasma load to the impedance of an RF generator. A controller including an iterative learning controller may adjust the capacitance of a variable capacitor to match the impedance of the plasma load and the impedance of the RF generator.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

1. A system for manufacturing a semiconductor device, comprising:
a main system controller to provide a process recipe for manufacturing a semiconductor device and identification information indicating one of a plurality of operations in the process recipe;
a sub-system controller to set a process control variable based on the process recipe and the identification information received from the main system controller; and
a process module to perform the process recipe based on an input value determined by the process control variable, wherein the sub-system controller includes:
a memory to store information indicative of a history of process control variables determined in the operations;
a basic controller to generate a basic process control variable based on a current value of the input value measured using a sensor and process control variables of an immediately previous operation; and
an iterative learning controller to generate a learning process control variable based on the basic process control variable and the information indicative of the history of the process control variables stored in the memory, wherein process control variables of a current operation are to be determined based on basic process control variables and learning process control variables.

2. The system as claimed in claim 1, wherein:
the sub-system controller includes an impedance matcher, and
the process control variable is capacitance of the impedance matcher.

3. The system as claimed in claim 2, wherein:
the process module is to perform the process recipe based on output of a voltage or current determined by the capacitance of the impedance matcher, and
the basic controller is to generate the basic process control variable based on a phase difference obtained by measuring the determined voltage or current.

4. The system as claimed in claim 1, wherein:
the iterative learning controller is to generate the learning process control variable based on a first variable calculated based on a product of the basic process control variable by an iterative learning control gain and a second variable obtained by filtering the information indicative of the history of the process control variables using a finite impulse response (FIR) filter.

5. The system as claimed in claim 4, wherein the iterative learning control gain has a value larger than 0 and smaller than 1.

6. The system as claimed in claim 1, wherein the basic controller is to generate the basic process control variable using proportional-integral (PI) control for the current value measured using the sensor.

7. The system as claimed in claim 1, wherein the main system controller includes a cluster tool controller (CTC) and a process module controller (PMC).

8. The system as claimed in claim 1, wherein the information indicative of the history of the process control variables includes values of process control variables before and after a digital control point of an operation that comes before an operation corresponding to the identification information.

9. The system as claimed in claim 1, wherein:
the sub-system controller includes a voltage generator, and
the process control variable is a switching control variable of the voltage generator.

10. The system as claimed in claim 1, wherein:
the sub-system controller includes a mass flow controller, and
the process control variable is an actuator control variable of the mass flow controller.

11. The system as claimed in claim 10, wherein:
the sub-system controller includes a chamber pressure controller, and
the process control variable is an actuator control variable of the chamber pressure controller.

12. A system for manufacturing a semiconductor device, includes:
a main system controller to provides a plasma etch recipe for manufacturing a semiconductor device and identification information indicating one of
a plurality of operations in the plasma etch recipe;
an impedance matcher to set capacitance of a variable capacitor based on the plasma etch recipe and the identification information received from the main system controller; and
a plasma chamber which performs the plasma etch recipe based on a value of a voltage or current determined by the capacitance of the variable capacitor, wherein the impedance matcher includes:
a memory to store information indicative of a history of capacitances of the variable capacitor determined in the operations;
a basic controller to generate a basic process control variable based on a value of a current or voltage applied to the plasma chamber and capacitances of the variable capacitor in an immediately previous operation; and
an iterative learning controller to generate a learning process control variable based on the basic process control variable and the information indicative of the history of the capacitances of the variable capacitor stored in the memory, wherein capacitances of the variable capacitor in a current operation are to be determined based on basic process control variables and learning process control variables.

13. The system as claimed in claim 12, wherein the iterative learning controller is to generate the learning process control variable based on a first variable calculated based on a product of the basic process control variable by an iterative learning control gain and a second variable obtained by filtering the information indicative of the history of the capacitances of the variable capacitor using an FIR filter.

14. The system as claimed in claim 13, wherein the iterative learning control gain has a value larger than 0 and smaller than 1.

15. The system as claimed in claim 13, wherein the capacitance of the variable capacitor is a value obtained based on a sum of the basic process control variable and the learning process control variable.

16. The system as claimed in claim 12, wherein:
the plasma chamber is to perform the plasma etch recipe based on output of a voltage or current determined by capacitance of the impedance matcher, and
the basic controller is to generate the basic process control variable based on a phase difference obtained by measuring the determined voltage or current.

17. A method for manufacturing a semiconductor device, the method comprising:
providing a process recipe for manufacturing a semiconductor device and identification information indicating one of a plurality of operations in the process recipe from a main system controller to a sub-system controller;
generating a basic process control variable based on process control variables of an operation immediately before a current operation indicated by the identification information and an input value provided to a process module;
generating a learning process control variable based on the basic process control variable and information indicative of a history of process control variables; and
determining a process control variable of the current operation based on the basic process control variable and the learning process control variable.

18. The method as claimed in claim 17, wherein the process control variable is capacitance of an impedance matcher in the sub-system controller.

19. The method as claimed in claim 17, wherein determining the process control variable of the current operation based on the basic process control variable and the learning process control variable includes determining the process control variable of the current operation based on a sum of the basic process control variable and the learning process control variable.

20. The method as claimed in claim 17, wherein the learning process control variable is generated based on a first variable calculated based on a product of the basic process control variable and an iterative learning control gain and a second variable obtained by filtering the information indicative of the history of the process control variables using an FIR filter.

21. (canceled)
